(19) United States
(12) Patent Application Publication
(10) Pub. No.: US 2025/0263828 A1
(43) Pub. Date: Aug. 21, 2025

(54) MOLYBDENUM SPUTTERING TARGET WITH HIGH TRANSVERSE RUPTURE STRENGTH

(71) Applicant: Honeywell International Inc., Charlotte, NC (US)

(72) Inventors: Xiaodan Wu, Spokane, WA (US); Susan D. Strothers, Mead, WA (US); Rashmi Mohanty, Liberty Lake, WA (US)

(21) Appl. No.: 19/040,855

(22) Filed: Jan. 29, 2025

Related U.S. Application Data
(60) Provisional application No. 63/554,541, filed on Feb. 16, 2024.

(51) Int. Cl. C23C 14/34

(52) U.S. Cl. CPC C23C 14/3414

(57) ABSTRACT

A molybdenum sputtering target assembly includes molybdenum sputtering target diffusion bonded directly to a molybdenum backing plate. The molybdenum sputtering target consists of molybdenum and the molybdenum backing plate consists of molybdenum or a molybdenum alloy.

### CROSS-REFERENCE TO RELATED APPLICATION

This application claims priority to U.S. Provisional Application No. 63/554,541, filed Feb. 16, 2024, which is herein incorporated by reference in its entirety.

### TECHNICAL FIELD

The present disclosure relates to molybdenum sputtering target, methods of making a sputtering target and methods of selecting molybdenum material for the sputtering target. Molybdenum sputtering targets can be used in semiconductor fabrication.

### BACKGROUND

Physical vapor deposition methodologies are used extensively for forming thin films of material over a variety of substrates. One area of importance for such deposition technology is semiconductor fabrication. A diagrammatic view of a portion of an exemplary physical vapor deposition (“PVD”) apparatus 8 is shown in FIG. 1. In one configuration, a sputtering target assembly 10 comprises a backing plate 12 having a target 14 bonded thereto. A substrate 18 such as a semiconductive material wafer is within the PVD apparatus 8 and provided to be spaced from the target 14. A surface 16 of target 14 is a sputtering surface. As shown, the target 14 is disposed above the substrate 18 and is positioned such that sputtering surface 16 faces substrate 18. In operation, sputtered material 22 is displaced from the sputtering surface 16 of target 14 and used to form a coating (or thin film) 20 over substrate 18.

Copper and aluminum are currently used for interconnect material in semiconductor manufacturing. Molybdenum is a next-generation candidate for interconnect material for advanced technology nodes. High power is typically required to sputter a molybdenum sputtering target. Thus, a diffusion-bonded target may be necessary. The most common backing plate material is a copper alloy. However, molybdenum and copper alloys have very different coefficients of thermal expansion (CTE). The CTE of molybdenum is 4.8 μm/(m·K), while the CTE of copper alloys can be around 20 μm/(m·K), depending on the alloy. During cooling down from either the diffusion bonding temperature or the duty cycle of the sputtering, the length change of a molybdenum target blank is much smaller than that of copper alloy backing plate as per the equation ΔL=Lo*a*ΔT (ΔL is the length change, Lo is the original length, a is the CTE, ΔT is the temperature change). Therefore, there is great thermal stress at the bonding interface between the molybdenum target and copper alloy backing plate, leading to either debonding or the molybdenum target cracking.

An improved molybdenum sputtering target assembly is needed.

### SUMMARY

In embodiment 1, a method for selecting molybdenum powder for a powder metallurgy sputtering target includes vacuum hot pressing a sample high purity powder molybdenum from a source to form a specimen; determining a transverse rupture strength of the specimen; and selecting the source for powder molybdenum for manufacture of powder metallurgy molybdenum sputtering targets if the transverse rupture strength of the specimen is greater than or equal to a predetermined value.

In embodiment 2, the method of embodiment 1, wherein the predetermined value is about 120 ksi (827 MPa).

In embodiment 3, the method of embodiment 1, wherein the sample high purity powder molybdenum consists of molybdenum and inevitable impurities.

In embodiment 4, the method of embodiment 1, wherein the predetermined value is about 150 ksi (1034 MPa).

In embodiment 5, the method of embodiment 1, wherein transverse rupture strength is determined by ASTM B528-16.

In embodiment 6, a sputtering target assembly includes a powder metallurgy high purity molybdenum sputtering target having a transverse rupture strength of at least 120 ksi (827 MPa); and a copper alloy backing plate diffusion bonded to the sputtering target.

In embodiment 7, the sputtering target assembly of embodiment 6, wherein the sputtering target has a transverse rupture strength of at least 150 ksi (1034 MPa).

In embodiment 8, the sputtering target assembly of embodiment 6, wherein the copper alloy backing plate is a copper-zinc backing plate.

In embodiment 9, the sputtering target assembly of embodiment 6, wherein the high purity molybdenum sputtering target consists of molybdenum and inevitable impurities.

In embodiment 10, the sputtering target assembly of embodiment 6, wherein an aluminum interlayer is between the powder metallurgy high purity molybdenum sputtering target and the copper alloy backing plate.

In embodiment 11, a method of making a sputtering target assembly includes selecting a powder molybdenum wherein the powder molybdenum produces a specimen having a transverse rupture strength of at least a predetermined value; forming the powder metallurgy sputtering target from the selected powder molybdenum; and attaching the powder metallurgy sputtering target to a backing plate, wherein the predetermined value is 120 ksi (827 MPa).

In embodiment 12, the method of embodiment 11, wherein the powder molybdenum consists of molybdenum and inevitable impurities.

In embodiment 13, the method of embodiment 11, wherein the predetermined value is 150 ksi (1034 MPa).

In embodiment 14, the method of embodiment 11, wherein transverse rupture strength is determined by ASTM B528-16.

In embodiment 15, the method of embodiment 11, wherein attaching the powder metallurgy sputtering target to a backing plate includes attaching the powder metallurgy sputtering target to a copper alloy backing plate.

In embodiment 16, the method of embodiment 15, wherein attaching the powder metallurgy sputtering target to a copper alloy backing plate includes diffusion bonding the powder metallurgy sputtering target to a copper alloy backing plate.

In embodiment 17, the method of embodiment 15, wherein the copper alloy backing plate is a copper-zinc backing plate.

In embodiment 18, the method of embodiment 17, and further including an aluminum interlayer between the copper-zinc backing plate and the powder metallurgy sputtering target.

In embodiment 19, the method of embodiment 11, wherein before selecting the powder molybdenum a specimen is formed using the powder molybdenum, and the transverse rupture strength of the specimen is determined.

In embodiment 20, the method of embodiment 11, wherein forming the powder metallurgy sputtering target includes hot pressing the selected powder molybdenum.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a schematic illustration of a sputtering apparatus.

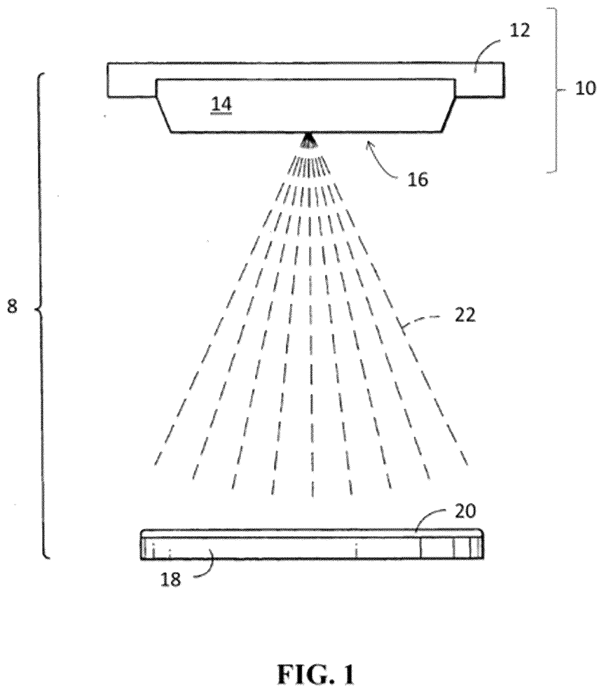

FIG. 2 is a schematic cross-sectional illustration of an exemplary molybdenum sputtering target assembly.

FIG. 3 is a block diagram for making molybdenum sputtering target.

FIG. 4 is a block diagram for selecting molybdenum powder for a sputtering target.

FIG. 5 is a schematic illustration for Example 2.

### DETAILED DESCRIPTION

Disclosed herein is an improved molybdenum sputtering target and a method of making the same. A method of selecting molybdenum powder for the sputtering target is also disclosed.

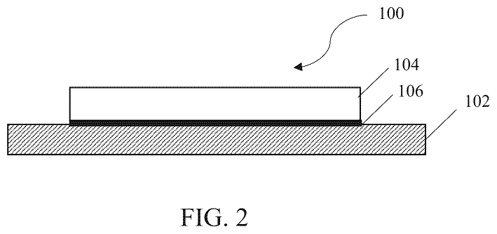

FIG. 2 is a schematic cross-sectional view of sputtering target assembly 100 which includes backing plate 102 and molybdenum sputtering target 104. In some embodiments, backing plate 102 and molybdenum sputtering target 104 are joined by a diffusion bond.

In some embodiments, molybdenum sputtering target 104 is formed from 100% molybdenum and inevitable impurities. For example, molybdenum sputtering target 104 can consist of or consistent essentially of molybdenum. Sputtering target 104 has a sufficient average grain for interconnect material. For example, molybdenum sputtering target 104 has an average grain size less than about 100 micrometers (μm). In some examples, molybdenum sputtering target 104 has an average grain size less than about 50 μm.

As described herein, molybdenum sputtering target 104 can be formed from powder metallurgy. For example, molybdenum sputtering target 104 can be formed by vacuum hot pressing.

In some embodiments, backing plate 102 can be formed from a copper alloy, such as a copper zinc alloy. In some embodiments, interlayer 106 can be positioned between backing plate 102 and sputtering target 104. For example, an aluminum interlayer 106 can be positioned between backing plate 102 and sputtering target 104.

Molybdenum sputtering target 104 and backing plate 102 are diffusion bonded to one another. In some embodiments, molybdenum sputtering target 104 and backing plate 102 are bonded by hot isostatic pressing (HIP) or vacuum hot press.

Thermal stress at the bonding interface between molybdenum sputtering target 104 and backing plate 102 occur as the sputtering target assembly cools following diffusion bonding. Thermal stress at the bonding interface can also occur during the duty cycle of the sputtering. The thermal stress can cause either debonding or molybdenum sputtering target 104 to crack.

It has been found that using a molybdenum sputtering target 104 with a high transverse rupture strength (TRS) provides a powder metallurgy sputtering target that has a lower likelihood of cracking. In one example, molybdenum sputtering target 104 has a TSR of at least 120 kilopounds per square inch (ksi) (827 megapascals (MPa)). In another example, molybdenum sputtering target 104 has a TSR of at least 150 ksi (1034 MPa).

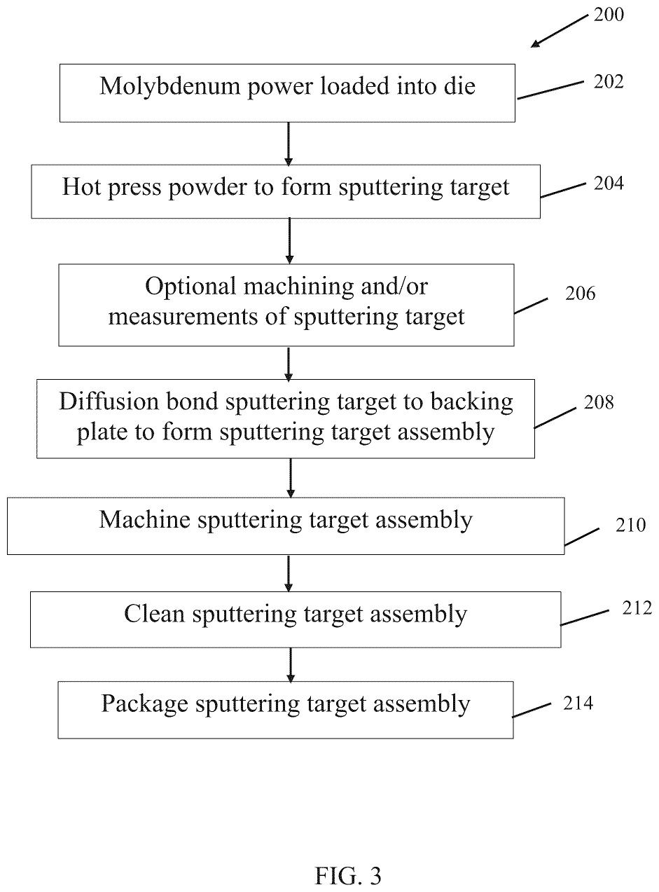

In some embodiments, molybdenum sputtering target 104 is manufactured using high purity molybdenum powder and vacuum hot pressing. FIG. 3 is a diagram of process 200 for making molybdenum sputtering target 104. In step 202, powder is loaded into the die, such as a graphite die, of a vacuum hot press machine. The powder can be a high purity molybdenum power. For example, the molybdenum powder can have 100% purity with inevitable impurities. That is, the molybdenum powder can consist of molybdenum and inevitable impurities.

In step 204, the powder in the die is vacuum hot pressed using a vacuum hot press machine to form a molybdenum sputtering target. In some examples, the vacuum hot press is at a temperature of over about 1600 degrees Celsius (° C.) (about 2912 degree Fahrenheit), a hydraulic pressure of over about 3 ksi (20.7 MPa) and uses a hold time of at least 2 hours. In some embodiments, the vacuum hot press is operated at a temperature from about 1600° C. (about 2912 degree Fahrenheit) to about 1780° C. (about 3236 degree Fahrenheit), a hydraulic press of about 3 ksi to about 4 ksi (about 20.7 MPa to about 27.6 MPa) and a hold time of about 2 hours to about 4 hours. After the vacuum hot press, the sputtering target has a TSR of at least 120 ksi (827 MPa) or of at least 150 ksi (1034 MPa).

Optionally, in step 206, after the hot press, the molybdenum sputtering target can be machined and/or measurements can be taken. For example, the density of the sputtering target can be determined. In some embodiments, the sputtering target is machined, the density is tested and then the sputtering target is machined a second time.

In step 208, the molybdenum sputtering target is bonded to a backing plate to form a sputtering target assembly. In some embodiments, the sputtering target can be diffusion bonded to a copper alloy, such as a copper zinc alloy backing plate.

After bonding, the sputtering target assembly is machined in step 210.

In step 212, the sputtering target is cleaned to remove debris from the surface of the sputtering target assembly from the manufacturing process. The sputtering target assembly is packaged in step 214. For example, the sputtering target assembly can be placed into plastic packaging material.

The transverse rupture strength defines the stress, calculated from the flexure formula, required to break a specimen as a simple beam supported near the ends and applying the force midway between the fixed line center of the supports. The transverse rupture strength of a powder metallurgy specimen, such as sputtering target 104, can be determined by ASTM B528-16. This is a destructive test. In some embodiments, the TRS is used to select the molybdenum powder used to form the sputtering target of method 200. TRS is not a standard design value and previously has not been considered when selecting source materials. Because the TRS analysis is a destructive test, it is not possible to determine the TRS of a sputtering target that is to be used. Rather, the TRS of the powder must be evaluated for use in the sputtering target.

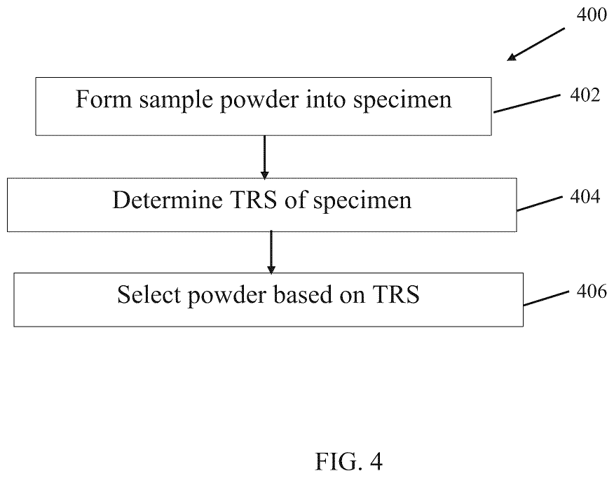

FIG. 4 is a diagram of process 400 for evaluating and selecting molybdenum for use in a sputtering target. In step 402, a sample of molybdenum powder to be evaluated is formed into powder metallurgy specimen. The powder should be consolidated, and a specimen collected from material using the same process in which the powder will be used to form the desired sputtering target. For example, when selecting molybdenum powder for the sputtering target of process 200, the molybdenum powder sample is processed according to that of process 200.

In step 404, the TRS of the specimen is determined. For example, the specimen can be tested according to ASTM B528-16 to determine the TRS of the specimen.

In step 406, the powder used to make high purity molybdenum sputtering targets is selected based on the TRS of step 404. In some embodiments, the powder can be selected if the TRS of the specimen is equal to or greater than a predetermined value. In some embodiments, if the specimen has a TSR of at least 120 ksi (827 MPa) or of at least 150 ksi (1034 MPa), the molybdenum powder may be used to make high purity diffusion bonded molybdenum sputtering targets. In some embodiments, the specimen may not break using ASTM B528-16. In this situation, the specimen is considered to have a TSR of at least 150 ksi (1034 MPa) and the powder can be used to form a high purity molybdenum sputtering target.

As used herein, “about” can mean±1%, ±2%, ±3%, ±4% or ±5%.

### Example 1

Hot pressed molybdenum samples were prepared using various sources of molybdenum powder. Each molybdenum powder was 100% purity molybdenum with inevitable impurities. The samples were prepared by vacuum hot pressing the molybdenum powder in a graphite die at 1740° C. (3164 degree Fahrenheit) and at a hydraulic pressure of 3.55 ksi (24.5 MPa) for a hold time of 3 hours.

The samples were then tested using ASTM B528-16 to determine the transverse rupture strength of each powder metallurgy sample. The results are provided in Table 1.

TABLE 1

| Sample | TRS (ksi) |
|---|---|
| #1 | 177.09 |
| #2 | 205.60 |
| #3 | 202.60 |
| #4 | 192.55 |
| #5 | Sample didn't break |
| #6 | Sample didn't break |

Each of the tested molybdenum powders tested resulted in a sample having a TRS of at least 120 ksi (827 MPa). Thus, each powder would be suitable for use in a high purity molybdenum sputtering target which is diffusion bonded to a backing plate.

### Example 2

A sputtering target assembly was manufactured and the sputtering target/backing plate bond was analyzed. First, a full size molybdenum sputtering target was formed using 100% molybdenum powder and vacuum hot pressing as described in Example 1. An additional molybdenum sputtering target blank was processed using the same parameters. The sputtering target blank had a TRS of 197.16 ksi (1359 MPa).

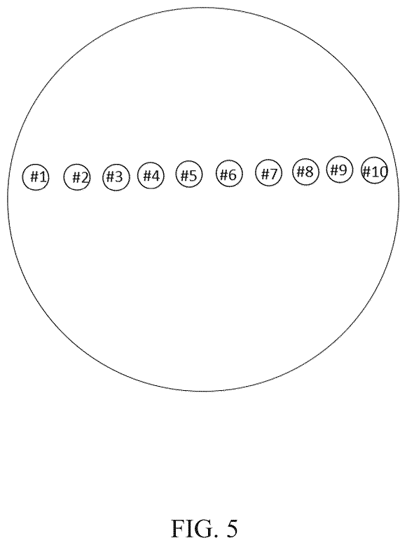

The sputtering target was diffusion bonded to a copper-zinc alloy backing plate with an aluminum interlayer. The high-strength molybdenum sputtering target survived the diffusion bonding process; the sputtering target did not crack. The percent bond was analyzed using a C-Scan. The C-Scan showed 100% bond. The bond strength between the sputtering target and interlayer and between the interlayer and the backing plate was determined using a ram tensile test method as described in Zatorski, Z. (2007) Evaluation of Steel Clad Plate Weldability Using Ram Tensile Test Method. Engineering Transactions, 55(3), 229-238.” Samples were taken across the diameter of the sputtering target as shown in FIG. 5. The results are provided in Table 2.

TABLE 2

| | Sample | Bond Strength (ksi) |
|---|---|---|
| Sputter target to | 1 | 8.2 |
| Al interlayer | 2 | 12.8 |
| | 3 | 8.6 |
| | 4 | 13.9 |
| | 5 | 14.1 |
| Al interlayer to | 6 | 8.8 |
| copper-zinc | 7 | 12.9 |
| backing plate | 8 | 14.4 |
| | 9 | 14.2 |
| | 10 | 13.9 |

The average bond strength of the sputtering target to Al interlayer bond was 11.5 ksi (79.3 MPa). The average bond strength of the Al interlayer to copper-zinc backing plate was 12.9 ksi (88.9 MPa).

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above-described features.

What is claimed is:

1. A method for selecting molybdenum powder for a powder metallurgy sputtering target, the method comprising:
vacuum hot pressing a sample high purity powder molybdenum from a source to form a specimen;
determining a transverse rupture strength of the specimen; and
selecting the source for powder molybdenum for manufacture of powder metallurgy molybdenum sputtering targets if the transverse rupture strength of the specimen is greater than or equal to a predetermined value.

2. The method of claim 1, wherein the predetermined value is about 120 ksi (827 MPa).

3. The method of claim 1, wherein the sample high purity powder molybdenum consists of molybdenum and inevitable impurities.

4. The method of claim 1, wherein the predetermined value is about 150 ksi (1034 MPa).

5. The method of claim 1, wherein transverse rupture strength is determined by ASTM B528-16.

6. A sputtering target assembly comprising:
a powder metallurgy high purity molybdenum sputtering target having a transverse rupture strength of at least 120 ksi (827 MPa); and
a copper alloy backing plate diffusion bonded to the sputtering target.

7. The sputtering target assembly of claim 6, wherein the sputtering target has a transverse rupture strength of at least 150 ksi (1034 MPa).

8. The sputtering target assembly of claim 6, wherein the copper alloy backing plate is a copper-zinc backing plate.

9. The sputtering target assembly of claim 6, wherein the high purity molybdenum sputtering target consists of molybdenum and inevitable impurities.

10. The sputtering target assembly of claim 6, wherein an aluminum interlayer is between the powder metallurgy high purity molybdenum sputtering target and the copper alloy backing plate.

11. A method of making a sputtering target assembly, the method comprising:
selecting a powder molybdenum wherein the powder molybdenum produces a specimen having a transverse rupture strength of at least a predetermined value;
forming the powder metallurgy sputtering target from the selected powder molybdenum; and
attaching the powder metallurgy sputtering target to a backing plate, wherein the predetermined value is 120 ksi (827 MPa).

12. The method of claim 11, wherein the powder molybdenum consists of molybdenum and inevitable impurities.

13. The method of claim 11, wherein the predetermined value is 150 ksi (1034 MPa).

14. The method of claim 11, wherein transverse rupture strength is determined by ASTM B528-16.

15. The method of claim 11, wherein attaching the powder metallurgy sputtering target to a backing plate includes attaching the powder metallurgy sputtering target to a copper alloy backing plate.

16. The method of claim 15, wherein attaching the powder metallurgy sputtering target to a copper alloy backing plate includes diffusion bonding the powder metallurgy sputtering target to a copper alloy backing plate.

17. The method of claim 15, wherein the copper alloy backing plate is a copper-zinc backing plate.

18. The method of claim 17, and further including an aluminum interlayer between the copper-zinc backing plate and the powder metallurgy sputtering target.

19. The method of claim 11, wherein before selecting the powder molybdenum a specimen is formed using the powder molybdenum, and the transverse rupture strength of the specimen is determined.

20. The method of claim 11, wherein forming the powder metallurgy sputtering target includes hot pressing the selected powder molybdenum.
